(19) United States
(12) Patent Application Publication
(10) Pub. No.: US 2025/0380581 A1
(43) Pub. Date: Dec. 11, 2025

(54) DISPLAY PANEL AND DISPLAY DEVICE

(71) Applicant: HKC CORPORATION LIMITED, SHENZHEN (CN)

(72) Inventors: Qin LIANG, SHENZHEN (CN); Yangling TANG, SHENZHEN (CN); Zhisheng XIE, SHENZHEN (CN); Xiufeng ZHOU, SHENZHEN (CN); Pei XU, SHENZHEN (CN)

(73) Assignee: HKC CORPORATION LIMITED, SHENZHEN (CN)

(21) Appl. No.: 19/219,632

(22) Filed: May 27, 2025

(30) Foreign Application Priority Data
Jun. 11, 2024 (CN) 202410750224.8

(51) Int. Cl. H10K 59/123; H10K 59/122; H10K 59/124; H10K 59/35

(52) U.S. Cl. CPC H10K 59/123; H10K 59/122; H10K 59/124; H10K 59/352; H10K 59/353; H10K 59/351

(57) ABSTRACT

A display panel and a display device are provided. A planarization layer covers a pixel driving layer and defines connecting holes. A pixel defining layer is disposed on a side of the planarization layer away from the pixel driving layer and defines pixel openings. An isolation structure protrudes from the pixel defining layer and surrounds the pixel openings. In a surrounding direction of the isolation structure, a sidewall of the isolation structure includes at least one linear sidewall segment. An orthographic projection of the sidewall of the isolation structure projected on the planarization layer covers the connecting holes. An orthographic projection of the linear sidewall segment on the planarization layer at least partially covers the connecting holes.

### CROSS-REFERENCE TO RELATED APPLICATIONS

This application claims priority to Chinese Patent Application No. 202410750224.8, filed on Jun. 11, 2024, in the National Intellectual Property Administration of China, the contents of which are herein incorporated by reference in their entireties.

### TECHNICAL FIELD

The present disclosure relates to the field of display technologies, and in particular to a display panel and a display device.

### BACKGROUND

An organic light-emitting diode (OLED) display device is a device that realizes graphical display through utilizing a reversible color-changing phenomenon of an organic semiconductor material under current drive. The OLED display device offers advantages, such as ultra-lightweight, ultra-thin profile, high brightness, wide viewing angle, low voltage, low power consumption, fast response, high definition, shock resistance, flexibility, low cost, simple manufacturing process, low material usage, high luminous efficiency, and wide operating temperature range, etc. Therefore, an OLED display technology is considered the most promising next-generation display technology.

However, during a manufacturing process of an existing OLED display panel, it is required to define a via in a planarization layer, which tends to cause uneven deposition of an anode, thereby affecting the light-emitting performance of the display panel.

### SUMMARY

A first technical solution of the present disclosure may provide a display panel. The display panel may include a pixel driving layer, a planarization layer, a pixel defining layer, a plurality of sub-pixels, and an isolation structure. The planarization layer may cover the pixel driving layer and define a plurality of connecting holes. The pixel defining layer may be disposed on a side of the planarization layer away from the pixel driving layer and define a plurality of pixel openings. Each of the plurality of sub-pixels may be disposed in a corresponding one of the plurality of pixel openings. An anode of each of the plurality of sub-pixels may be electrically connected to the pixel driving layer through a corresponding one of the plurality of connecting holes. The isolation structure may protrude from the pixel defining layer and surround the plurality of pixel openings. In a surrounding direction of the isolation structure, a sidewall of the isolation structure may include a sidewall segment extending linearly. The number of the sidewall segment extending linearly may be at least one. The sidewall segment extending linearly may be defined as a linear sidewall segment. An orthographic projection of the sidewall of the isolation structure projected on the planarization layer may cover the plurality of connecting holes. An orthographic projection of the linear sidewall segment on the planarization layer at least partially may cover the plurality of connecting holes.

A second technical solution of the present disclosure may provide a display device. The display device may include the display panel mentioned above.

### BRIEF DESCRIPTION OF THE DRAWINGS

In order to more clearly illustrate the technical solutions in some embodiments of the present disclosure, a brief introduction will be given below to the drawings required in the description of the embodiments. It is evident that the drawings described below are merely some embodiments of the present disclosure, and a person of ordinary skills in the art may obtain other drawings based on the following drawings without creative work.

FIG. 1 is a schematic structural view of a display panel according to some embodiments of the present disclosure.

FIG. 2 is a schematic structural view of a first embodiment of a sub-pixel, an isolation structure, and a connecting hole according to the present disclosure.

FIG. 3 is a schematic sectional structural view at E-E in FIG. 1 according to some embodiments of the present disclosure.

FIG. 4 is a schematic enlarged structural view at M in FIG. 3 according to some embodiments of the present disclosure.

FIG. 5 is a schematic sectional structural view at F-F in FIG. 1 according to some embodiments of the present disclosure.

FIG. 6 is a schematic structural view of a second embodiment of a sub-pixel, an isolation structure, and a connecting hole according to the present disclosure.

FIG. 7 is a schematic structural view of a third embodiment of a sub-pixel, an isolation structure, and a connecting hole according to the present disclosure.

FIG. 8 is a schematic structural view of a fourth embodiment of a sub-pixel, an isolation structure, and a connecting hole according to the present disclosure.

FIG. 9 is a schematic structural view of a fifth embodiment of a sub-pixel, an isolation structure, and a connecting hole according to the present disclosure.

FIG. 10 is a schematic structural view of a first embodiment of a pixel unit, an isolation structure, and a connecting hole according to the present disclosure.

FIG. 11 is a schematic structural view of a second embodiment of a pixel unit, an isolation structure, and a connecting hole according to the present disclosure.

FIG. 12 is a schematic structural view of a third embodiment of a pixel unit, an isolation structure, and a connecting hole according to the present disclosure.

FIG. 13 is a schematic sectional structural view at E-E in FIG. 1 according to some other embodiments of the present disclosure.

FIG. 14 is a schematic sectional structural view at F-F in FIG. 1 according to some other embodiments of the present disclosure.

### DETAILED DESCRIPTION

The following provides a detailed description of the technical solutions in some embodiments of the present disclosure with reference to the accompanying drawings.

In the following description, specific details such as particular system structures, interfaces, and technologies are presented for illustrative purposes and not for the purpose of limitation, to provide a thorough understanding of the present disclosure.

The technical solutions in some embodiments of the present disclosure will be clearly and completely described below with reference to the accompanying drawings. It is evident that the described embodiments are only part of the embodiments of the present disclosure and not all embodiments. Based on the embodiments of the present disclosure, all other embodiments obtained by a person of ordinary skills in the art without any creative work fall within the scope of the present disclosure.

The terms “first”, “second”, and “third” in the present disclosure are merely used for descriptive purposes and should not be construed as indicating or implying relative importance or implicitly indicating the quantity of the indicated technical features. Thus, the features limited by “first” “second” and “third” may explicitly or implicitly include at least one such feature. In the description of the present disclosure, “a plurality of” means at least two, for example, two, three, etc., unless specifically and explicitly limited otherwise. All directional indications (such as up, down, left, right, front, back, etc.) in the embodiments of the present disclosure are only used to explain the relative positional relationships, motion situations, etc. among the components under a specific posture (as shown in the figures). When the specific posture changes, the directional indications shall be changed accordingly. Furthermore, the terms “including” and “having” and any variations thereof, are intended to cover non-exclusive inclusion. For example, a process, method, system, product, or device that includes a series of steps or units is not limited to those explicitly listed steps or units but may further optionally include other steps or units not listed, or may further optionally include other inherent steps or units of such process, method, product, or device.

As referred to herein, “embodiment” means that a specific feature, structure, or characteristic described in connection with the embodiment may be included in at least one embodiment of the present disclosure. The appearance of the phrase in various places in the specification are not necessarily all referring to the same embodiment, nor are they mutually exclusive alternative embodiments. It is explicitly and implicitly understood by a person of ordinary skills in the art that the embodiments described herein may be combined with other embodiments.

Furthermore, it is to be understood that the use of the term “substantially” herein, unless otherwise defined with respect to a specific context, with respect to a numeric quantity or otherwise quantifiable relationship, e.g., perpendicularity or parallelism, is to be understood as indicating that quantity +−10%. Thus, for example, lines that are substantially perpendicular to one another may be at angles between 81° and 99° to one another. In a further example, dimensions that are substantially between 1 mm and 3 mm, for example, may range from 0.9 mm to 3.3 mm. In another example, an angle that is substantially in the range of 1 to 1.1 radians may be between 0.9 radians and 1.21 radians.

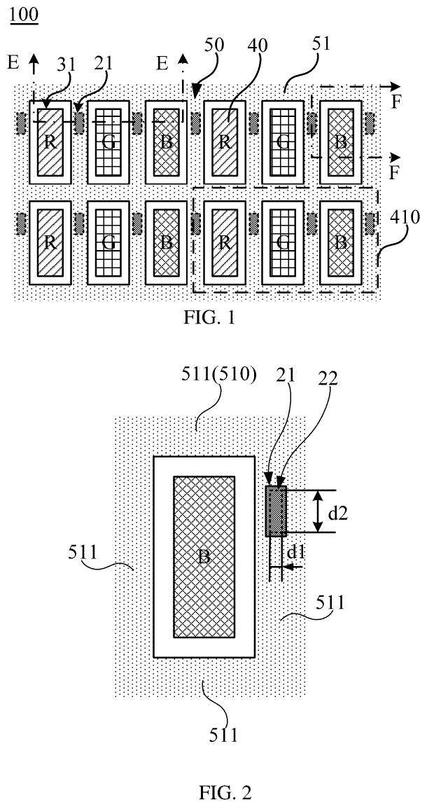

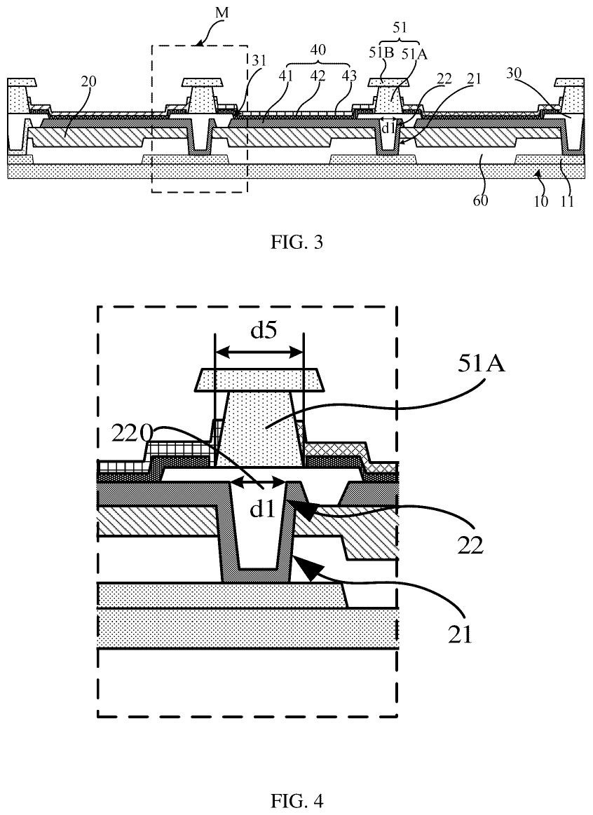

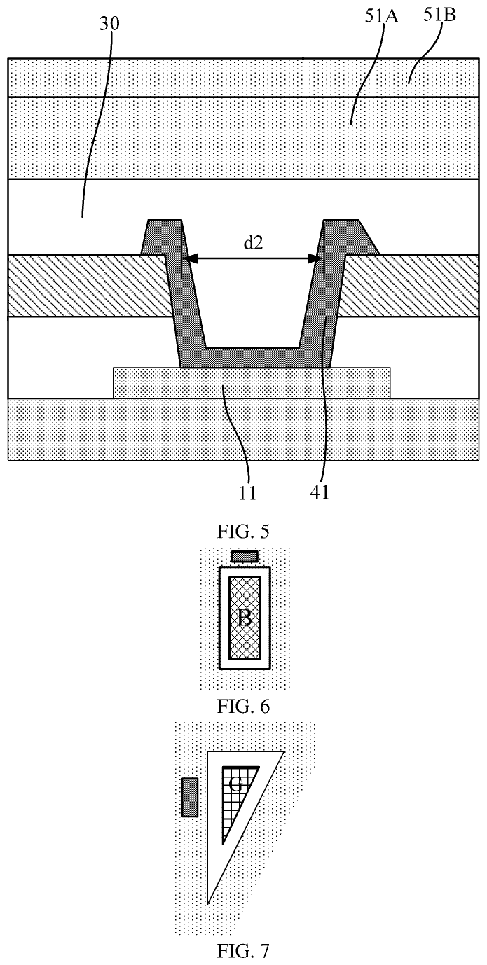

As shown in FIGS. 1-5, FIG. 1 is a schematic structural view of a display panel according to some embodiments of the present disclosure, FIG. 2 is a schematic structural view of a first embodiment of a sub-pixel, an isolation structure, and a connecting hole according to the present disclosure, FIG. 3 is a schematic sectional structural view at E-E in FIG. 1 according to some embodiments of the present disclosure, FIG. 4 is a schematic enlarged structural view at M in FIG. 3 according to some embodiments of the present disclosure, and FIG. 5 is a schematic sectional structural view at F-F in FIG. 1 according to some embodiments of the present disclosure.

Some embodiments of the present disclosure may provide a display panel 100. The display panel 100 may include a pixel driving layer 10, a planarization layer 20, a pixel defining layer 30, a plurality of sub-pixels 40, and an isolation structure 50.

The planarization layer 20 may cover the pixel driving layer 10. A plurality of connecting holes 21 may be defined on the planarization layer 20. The pixel defining layer 30 may be disposed on a side of the planarization layer 20 away from the pixel driving layer 10. A plurality of pixel openings 31 may be defined on the pixel defining layer 30. The plurality of sub-pixels 40 may be arranged in a one-to-one correspondence with the plurality of pixel openings 31. That is, each of the plurality of sub-pixels 40 may be disposed in a corresponding one of the plurality of pixel openings 31. For each of the plurality of sub-pixels 40, an anode 41 of the sub-pixel 40 may be electrically connected to the pixel driving layer 10 through the corresponding one of the plurality of connecting holes 21. The isolation structure 50 may protrude from the pixel defining layer 30 and surround the plurality of pixel openings 31. In a surrounding direction of the isolation structure 50, i.e., in a direction where the isolation structure 50 surrounds the corresponding pixel opening 31, a sidewall 51 of the isolation structure 50 may include a sidewall segment 510 extending linearly or in a straight line. The number of the sidewall segment 510 extending linearly or in a straight line may be at least one. The sidewall segment 510 of the isolation structure 50 that extends linearly or in a straight line may be defined as a linear sidewall segment 511. An orthographic projection of the sidewall 51 of the isolation structure 50 on the planarization layer 20 may cover the plurality of connecting holes 21. An orthographic projection of the linear sidewall segment 511 on the planarization layer 20 may at least partially cover the plurality of connecting holes 21.

Through defining the plurality of connecting holes 21 below the isolation structure 50, each connecting hole 21 may be arranged as far as possible from the corresponding pixel opening 31 without affecting a size of the corresponding pixel opening 31. As a result, when depositing the anode 41, a surface of the anode 41 at the corresponding pixel opening 31 may not become uneven due to a part of the anode 41 being deposited in the corresponding connecting hole 21, thereby reducing an occurrence of a reduction in flatness. In this way, a reduced light emission brightness of the plurality of sub-pixels 40 or a poor viewing angle light output effect of the plurality of sub-pixels 40 may be less likely to be caused, thereby improving the light-emitting performance of the display panel 100.

The pixel driving layer 10 may be configured to drive the plurality of sub-pixels 40 to emit light. A structure of the pixel driving layer 10 is not limited herein and may be selected based on actual needs.

The pixel driving layer may 10 include an output electrode 11. The anode 41 may be connected to the output electrode 11 of the pixel driving layer 10 through the corresponding connecting hole 21.

The plurality of connecting holes 21 defined on the planarization layer 20 may be spaced apart from each other. In a direction substantially perpendicular to the pixel driving layer 10, the plurality of connecting holes 21 may penetrate through the planarization layer 20. In a direction substantially perpendicular to the planarization layer 20, a cross-section of each connecting hole 21 may be an inverted trapezoid. For each connecting hole 21, an aperture of an end of the connecting hole 21 close to the pixel driving layer 10 may be smaller than an aperture of an end of the connecting hole 21 away from the pixel driving layer 10. The above configuration of the connecting hole 21 may facilitate the anode 41 covering a sidewall of the connecting hole 21 to be electrically connected with the pixel driving layer 10.

A material of the planarization layer 20 is not limited herein and may be selected based on actual needs.

The plurality of connecting holes 21 may be arranged in a one-to-one correspondence with the plurality of sub-pixels 40. In a direction substantially parallel to the pixel driving layer 10, each connecting hole 21 may extend along an extending direction of the sidewall 51 so as to maximize an area of the cross-section of the connecting hole 21 in the direction substantially parallel to the planarization layer 20. In this way, a contact area between the output electrode 11 and the anode 41 in the connecting hole 21 may be increased, thereby ensuring a good electrical connection between the anode 41 and the output electrode 11.

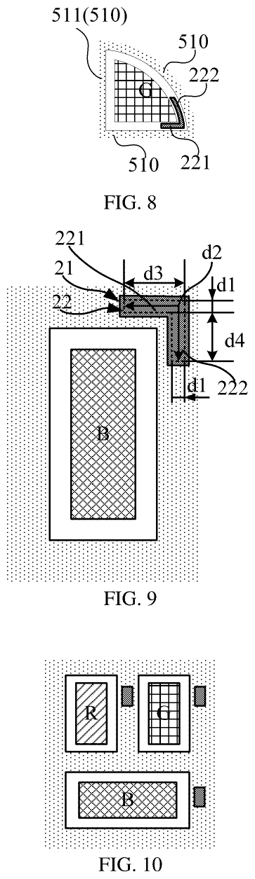

As shown in FIG. 1, FIG. 3, and FIGS. 6-9, FIG. 6 is a schematic structural view of a second embodiment of a sub-pixel, an isolation structure, and a connecting hole according to the present disclosure, FIG. 7 is a schematic structural view of a third embodiment of a sub-pixel, an isolation structure, and a connecting hole according to the present disclosure, FIG. 8 is a schematic structural view of a fourth embodiment of a sub-pixel, an isolation structure, and a connecting hole according to the present disclosure, and FIG. 9 is a schematic structural view of a fifth embodiment of a sub-pixel, an isolation structure, and a connecting hole according to the present disclosure.

Furthermore, in some embodiments, each connecting hole 21 may be arranged corresponding to one linear sidewall segment 511. In a direction substantially perpendicular to the pixel driving layer 10, the connecting hole 21 may at least partially overlap with the corresponding linear sidewall segment 511.

In a case where the connecting hole 21 fully overlaps with the corresponding linear sidewall segment 511 in the direction substantially perpendicular to the pixel driving layer 10, the connecting hole 21 may be defined to extend linearly or in a straight line (as shown in FIGS. 2, 6, and 7). In a case where the isolation structure 50 includes more than one linear sidewall segment 511, the connecting hole 21 may correspond to any one of the linear sidewall segments 511 of the corresponding isolation structure 50 (as shown in FIGS. 2 and 6).

In a case where the connecting hole 21 partially overlaps with the corresponding linear sidewall segment 511 in the direction substantially perpendicular to the pixel driving layer 10, the connecting hole 21 may partially extend linearly or in a straight line along the extending direction of the corresponding sidewall 51 (as shown in FIG. 8). It can be understood that in the surrounding direction of the isolation structure 50, the connecting hole 21 may be defined at a corner of the corresponding sidewall 51 (i.e., at an intersection of the linear sidewall segment 511 and a part of the sidewall 51 that is not the linear sidewall segment 511).

Designing the connecting hole 21 to extend linearly or in a straight line may facilitate the preparation of the connecting hole 21 on the planarization layer 20.

In some other embodiments, the connecting hole 21 may be arranged corresponding to adjacent two linear sidewall segments 511 of the same isolation structure 50. In the direction substantially perpendicular to the pixel driving layer 10, the connecting hole 21 may partially overlap with each of the corresponding adjacent two linear sidewall segments 511 (as shown in FIG. 9). That is, in the surrounding direction of the isolation structure 50, the connecting hole 21 may be defined corresponding to a bend of the sidewall 51 (i.e., at an intersection of two adjacent linear sidewall segments 511).

It should be noted that two adjacent sub-pixels 40 may share the same sidewall segment 510 of the isolation structure 50. In a case where the connecting hole 21 is defined corresponding to the shared sidewall segment 510, the isolation structure 50 that surrounds one sub-pixel 40 may correspond to multiple connecting holes 21 (i.e., one isolation structure 50 may cover multiple connecting holes 21), without departing from the principle that one sub-pixel 40 corresponds to one connecting hole 21. In other words, some embodiments of the present disclosure only may illustrate the number of the connecting hole 21 corresponding to one sub-pixel 40, without limiting the number of connecting hole 21 corresponding to one isolation structure 50. As shown in FIG. 1, one sub-pixel 40 may correspond to one connecting hole 21, while the isolation structure 50 surrounding the sub-pixel 40 may correspond to two connecting holes 21.

The description of the above embodiments is provided in a case where one connecting hole 21 corresponds to one linear sidewall segment 511 and the connecting hole 21 fully overlaps with the corresponding linear sidewall segment 511 in the direction substantially perpendicular to the pixel driving layer 10.

The display panel 100 may further include an insulating layer 60. The insulating layer 60 may be disposed between the pixel driving layer 10 and the planarization layer 20. In the direction substantially perpendicular to the pixel driving layer 10, the connecting hole 21 may penetrate through the insulating layer 60 to partially expose the output electrode 11 of the pixel driving layer 10, allowing or enabling the anode 41 to be electrically connected to the output electrode 11 through the corresponding connecting hole 21.

It can be understood that the insulating layer 60 and the planarization layer 20 may together or cooperatively define the plurality of connecting holes 21.

For each sub-pixel 40, the sub-pixel 40 may include an OLED. In some embodiments, the sub-pixel 40 may include an anode 41, a light-emitting layer 42, and a cathode 43 sequentially stacked on one another. The anode 41 may be disposed between the planarization layer 20 and the pixel defining layer 30. The cathodes 43 of the sub-pixels 40 may be electrically connected to each other through the isolation structure 50, enabling the cathodes 43 across the entire panel to be formed in a mesh-like manner, thereby helping improve the uniformity of the cathodes 43. The anodes 41 may be spaced apart from each other and spaces between the anodes 41 may be filled by the pixel defining layer 30, such that the anodes 41 may be insulated from each other.

The anode 41 may be disposed in the corresponding pixel opening 31, extend into the corresponding connecting hole 21, and further cover the sidewall of the corresponding connecting hole 21, enabling the anode 41 to be electrically connected to the pixel driving layer 10 through the corresponding connecting hole 21. In other words, a part of the anode 41 may be disposed in the corresponding pixel opening 31, while another part of the anode 41 may be deposited in the corresponding connecting hole 21 to be electrically connected to the pixel driving layer 10. The anode 41 deposited in the corresponding connecting hole 21 may cover the sidewall of the corresponding connecting hole 21. A part of the anode 41 that covers the sidewall of the corresponding connecting hole 21 and another part of the anode 41 that contacts the pixel driving layer 10 may together or cooperatively define a conductive groove 22.

The sub-pixel 40 may be substantially in a rectangular shape (as shown in FIG. 2 and FIG. 6), a triangular shape (as shown in FIG. 7), a fan shape (as shown in FIG. 8), or other shapes. The sub-pixel 40 may be a regular shape or an irregular shape. A shape of the sub-pixel 40 is not limited herein, as long as one side of the sub-pixel 40 is ensured to extend linearly or in a straight line.

In the above embodiments, the sub-pixels 40 may be arranged in an array. The display panel 100 may include the sub-pixels 40 of three different colors. Three sub-pixels 40 of different colors may cooperatively or together form a pixel unit 410. Within each pixel unit 410, the three sub-pixels 40 of different colors may be arranged side-by-side in sequence along a row direction of the sub-pixels 40. The sub-pixels 40 of three different colors may include a red pixel R, a green pixel G, and a blue pixel B. The pixel unit 410 may have a substantially rectangular shape.

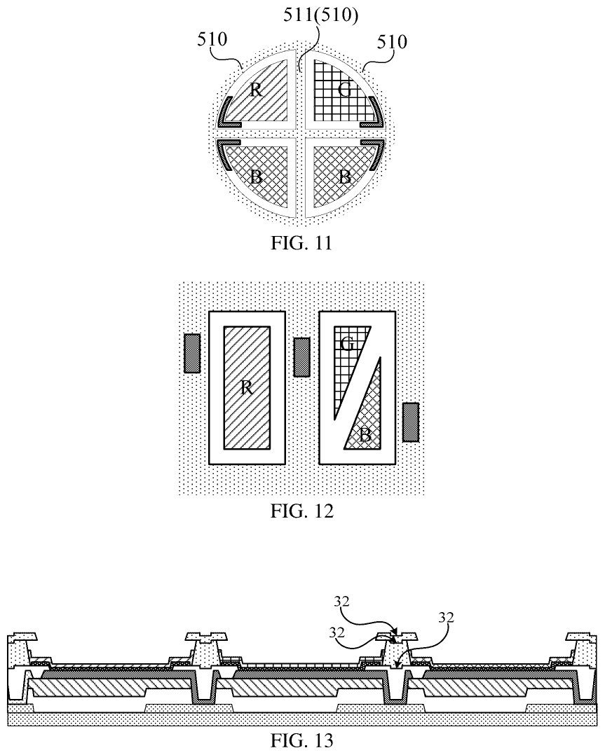

As shown in FIG. 1, FIG. 3, and FIGS. 10-12, FIG. 10 is a schematic structural view of a first embodiment of a pixel unit, an isolation structure, and a connecting hole according to the present disclosure, FIG. 11 is a schematic structural view of a second embodiment of a pixel unit, an isolation structure, and a connecting hole according to the present disclosure, and FIG. 12 is a schematic structural view of a third embodiment of a pixel unit, an isolation structure, and a connecting hole according to the present disclosure.

In some other embodiments, within the pixel unit 410, the three sub-pixels 40 of different colors may be arranged substantially in a rectangular shape as shown in FIG. 10, which includes three squares arranged in two layers, one layer with one sub-pixel, and another layer with two sub-pixels. In some embodiments, the three sub-pixels 40 of different colors may have other arrangements. The pixel unit 410 may further have a substantially circular shape (as shown in FIG. 11) or other shapes. The display panel 100 may include the sub-pixels 40 of more or fewer colors. A color of the sub-pixels 40 included in the display panel 100 may further be other colors. The number of sub-pixels 40 included in a single pixel unit 410 is not limited herein and may be selected based on actual needs. A shape of each sub-pixel 40 within the pixel unit 410 may be the same (as shown in FIG. 1, FIG. 10, and FIG. 11) or partially different (as shown in FIG. 12).

Sizes of the sub-pixels 40 of different colors in the pixel unit 410 are not limited herein, which may be selected based on actual needs.

The conductive grooves 22 may be arranged in a one-to-one correspondence with the connecting holes 21. An orthographic projection of the conductive groove 22 on the pixel driving layer 10 may be located within an orthographic projection of the corresponding connecting hole 21 on the pixel driving layer 10.

A sidewall of the conductive groove 22 and a sidewall of the corresponding connecting hole 21 that are adjacent to each other may be substantially arranged in parallel. It can be understood that in the direction substantially parallel to the planarization layer 20, a shape of a cross-section of the conductive groove 22 may be similar to a shape of a cross-section of the corresponding connecting hole 21. A width of a space between the conductive groove 22 and the corresponding connecting hole 21 may refer to a film thickness of the anode 41.

It should be understood that during the deposition process, a part of the anode 41 that is located in the connecting hole 21 may be prone to issues such as material accumulation and step coverage, resulting in uneven film thickness in the part of the anode 41 that is located in the connecting hole 21. In a case where the connecting hole 21 is defined under the corresponding pixel opening 31, a decrease in the flatness of the anode 41 at the corresponding pixel opening 31 may be likely caused, resulting in uneven thickness of the light-emitting layer 42 at the corresponding pixel opening 31, thereby affecting the light-emitting performance of the corresponding sub-pixel 40. In the above embodiments, the connecting hole 21 may be defined under the isolation structure 50. In this way, when depositing the anode 41, the deposition of the part of the anode 41 in the corresponding connecting hole 21 may not cause an uneven surface of the anode 41 at the corresponding pixel opening 31 and reduce the flatness.

The pixel definition layer 30 may define positions of the sub-pixels 40. In the direction substantially perpendicular to the pixel driving layer 10, for each sub-pixel 40, the pixel opening 31 may penetrate through the pixel definition layer 30 and expose at least a part of the anode 41, facilitating in the light-emitting layer 42 and the cathode 43 to be sequentially disposed on a side of the anode 41 away from the pixel driving layer 10.

The pixel definition layer 30 may include an inorganic material or an organic material. A material of the pixel definition layer 30 is not limited herein and may be selected based on actual needs. In the above embodiments, the pixel definition layer 30 may fill the conductive groove 22. A surface of a part of the pixel definition layer 30 corresponding to the conductive groove 22 and facing away from the pixel driving layer 10 may be flat.

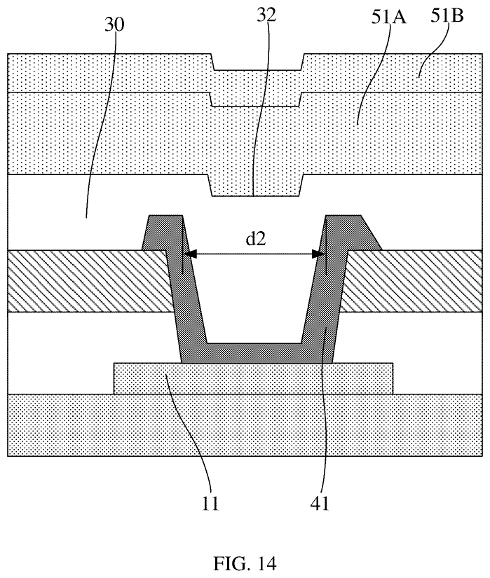

As shown in FIGS. 1-4, FIG. 13, and FIG. 14, FIG. 13 is a schematic sectional structural view at E-E in FIG. 1 according to some other embodiments of the present disclosure, and FIG. 14 is a schematic sectional structural view at F-F in FIG. 1 according to some other embodiments of the present disclosure.

It should be understood that in some other embodiments, after the anode 41 is formed or prepared, the pixel definition layer 30 may be disposed on a side of the planarization layer 20 away from the pixel driving layer 10. The pixel definition layer 30 may cover the conductive groove 22. A preparation or manufacturing process of the pixel definition layer 30 may define a recess 32 on a surface of a part of the pixel definition layer 30 corresponding to the conductive groove 22 and facing away from the pixel driving layer 10. That is, a surface of a side of the pixel definition layer 30 facing away from the conductive groove 22 may be non-flat. In this way, for a conductive portion 51A and an eave structure 51B subsequently disposed in the recess 32, a surface of a side of each of the conductive portion 51A and the eave structure 51B that faces away from the pixel driving layer 10 may similarly define the recess 32.

The isolation structure 50 may be disposed on a surface of a side of the pixel definition layer 30 facing away from the pixel driving layer 10. The isolation structure 50 may substantially be a ring-shaped structure. The ring-shaped structure may be a closed ring-shaped structure or an open ring-shaped structure.

In the above embodiments, the isolation structure 50 may be the closed ring-shaped structure.

A shape of an area surrounded or encircled by the isolation structure 50 may be similar to a shape of the sub-pixel 40 surrounded or encircled by the isolation structure 50.

In the direction substantially perpendicular to the pixel driving layer 10, the sidewall 51 of the isolation structure 50 may include the conductive portion 51A and the eave structure 51B stacked on one another in sequence. The eave structure 51B may shield the conductive portion 51A and extend beyond the conductive portion 51A in a direction substantially parallel to a plane where the pixel definition layer 30 is located. That is, an orthographic projection of the eave structure 51B on the pixel driving layer 10 may cover an orthographic projection of the conductive portion 51A. An area of the orthographic projection area of the eave structure 51B on the pixel driving layer 10 may be greater than an area of the orthographic projection area of the conductive portion 51A on the pixel driving layer 10. The cathodes 43 of the sub-pixels 40 may be electrically connected to each other through the conductive portion 51A. The eave structure 51B may be configured to adjust an evaporation angle of an evaporation material during the evaporation of the cathode 43 and the light-emitting layer 42 of the sub-pixel 40, facilitating in enabling the cathode 43 to cover the light-emitting layer 42 and achieve a good electrical connection with the conductive portion 51A.

A material of the eave structure 51B is not limited herein and may be selected based on actual needs. In the direction substantially perpendicular to the pixel driving layer 10, a width of the conductive portion 51A may gradually decrease in a direction toward or approaching the eave structure 51B, facilitating in the cathode 43 to lap with a side surface of the conductive portion 51A.

Further, the orthographic projection of the conductive portion 51A on the pixel driving layer 10 may cover the orthographic projection of the conductive groove 22 on the pixel driving layer 10. The conductive portion 51A may include a metal layer that is opaque. Through defining the conductive groove 22 below the conductive portion 51A, the conductive groove 22 may be located as far away as possible from the corresponding pixel opening 31 without affecting the size of the corresponding pixel opening 31, thereby facilitating in reducing the occurrence of reduced flatness of the anode 41 at the corresponding pixel opening 31.

A width direction of the conductive groove 22 may refer to a wall thickness direction of the corresponding isolation structure 51. A width of a groove opening 220 of the conductive groove 22 may be defined as a first size d1. The first size d1 may be less than 4 μm. The above design may ensure a good electrical connection between the anode 41 and the pixel driving layer 10 while minimizing the size of the conductive groove 22, thereby reducing the influence of the anode 41 at the corresponding connecting hole 21 on the flatness of the anode 41 at the corresponding pixel opening 31.

In a direction directed from the groove opening 220 of the conductive groove 22 to a bottom wall of the conductive groove 22, the width of the conductive groove 22 may gradually decrease.

A length direction of the conductive groove 22 may refer to an extending direction of the sidewall 51 that corresponds to the conductive groove 22. An extending length of the conductive groove 22 from an end of the groove opening 220 of the conductive groove 22 to another other end of the groove opening 220 of the conductive groove 22 in the length direction may be defined as a second size d2. The second size d2 may be greater than the first size d1. The above design may increase the extending length of the conductive groove 22 in the surrounding direction of the isolation structure 50 without affecting the size of the pixel opening 31, thereby increasing an area of the cross-section of the conductive groove 22 in the direction substantially parallel to the planarization layer 20, which facilitates in increasing the contact area between the anode 41 at the connecting hole 21 and the output electrode 11 and ensures the good electrical connection between the anode 41 and the pixel driving layer 10.

A pattern formed by the orthographic projection of the conductive groove 22 on the pixel driving layer 10 may be defined as a first projection pattern. A pattern formed by the orthographic projection of the conductive portion 51A on the pixel driving layer 10 may be defined as a second projection pattern. An edge of the first projection pattern and an edge of the corresponding second projection pattern that are adjacent to each other may be substantially arranged in parallel.

In other words, in the direction substantially parallel to the pixel driving layer 10, an edge of the conductive groove 22 and an edge the conductive portion 51A that are adjacent to each other may be arranged in parallel, thereby not only facilitating in the preparation or manufacture of the conductive groove 22, but also allowing for maximizing the width of the conductive groove 22 without changing the size of the conductive portion 51A. In this way, an area of the cross-section of the conductive groove 22 in the direction substantially parallel to the planarization layer 20 may be thus increased.

In some embodiments, the isolation structure 50 may substantially have a rectangular ring structure. The sub-pixel 40 may be substantially rectangular in shape. The conductive groove 22 may be defined at a corner of the rectangular ring structure. The first projection pattern may be substantially L-shaped (as shown in FIG. 9). As shown in FIG. 9, the conductive groove 22 may include a first part 221 extending linearly or in a straight line and a second part 222 extending linearly or in a straight line. The first part 221 and the second part 222 may intersect with each other. An extending length of the first part 221 may be defined as a third size d3. An extending length of the second part 222 may be defined as a fourth size d4. The second size d2 may be a sum of the third size d3 and the fourth size d4, i.e., d2=d3+d4.

It should be understood that, in some other embodiments, either the first part 221 or the second part 222 may extend in a non-linear manner (as shown in FIG. 8). As shown in FIG. 8, the first part 221 may extend linearly or in a straight line and the second part 222 may extend in a curved line.

In some other embodiments, the conductive groove 22 may be defined corresponding to an edge of the rectangular ring structure. The first projection pattern may substantially be rectangular in shape (as shown in FIG. 2).

In the above embodiments, the conductive groove 22 may be defined corresponding to an edge of the rectangular ring structure. The first projection pattern may substantially be rectangular in shape. In the wall thickness direction of the isolation structure 50, a width of an end of the conductive portion 51A away from the eave structure 51B may be defined as a fifth size d5. The fifth size d5 may be greater than the first size d1, ensuring that a bottom of the conductive portion 51A may cover the conductive groove 22.

In some other embodiments, the conductive groove 22 may be defined at a corner of the rectangular ring structure. The first projection pattern may be substantially L-shaped. The sub-pixels 40 may be in other shapes, such as a triangle, a parallelogram, or etc.

Some embodiments of the present disclosure may provide a display device. The display device may include the aforementioned display panel 100.

In the above embodiments, different aspects are emphasized respectively. Portions not described in detail in one embodiment may refer to relevant descriptions in other embodiments.

The above are merely exemplary embodiments of the present disclosure and should not be construed as limiting the scope of the present disclosure. Based on the description and drawings of the present disclosure, any equivalent structural or process modifications, or any direct or indirect applications in other related technical fields, shall fall within the scope of the present disclosure.

1. A display panel, comprising:
a pixel driving layer;
a planarization layer, covering the pixel driving layer and defining a plurality of connecting holes;
a pixel defining layer, disposed on a side of the planarization layer away from the pixel driving layer and defining a plurality of pixel openings;
a plurality of sub-pixels, each of the plurality of sub-pixels being disposed in a corresponding one of the plurality of pixel openings, wherein an anode of each of the plurality of sub-pixels is electrically connected to the pixel driving layer through a corresponding one of the plurality of connecting holes; and
an isolation structure, protruding from the pixel defining layer and surrounding the plurality of pixel openings;
wherein, in a surrounding direction of the isolation structure, a sidewall of the isolation structure comprises a sidewall segment extending linearly, the number of the sidewall segment extending linearly is at least one, and the sidewall segment extending linearly is defined as a linear sidewall segment; and
an orthographic projection of the sidewall of the isolation structure projected on the planarization layer covers the plurality of connecting holes, and an orthographic projection of the linear sidewall segment on the planarization layer at least partially covers the plurality of connecting holes.

2. The display panel as claimed in claim 1, wherein the plurality of connecting holes are arranged in a one-to-one correspondence with the plurality of sub-pixels, and in a direction substantially parallel to the pixel driving layer, the plurality of connecting holes extend along an extending direction of the sidewall.

3. The display panel as claimed in claim 1, wherein each of the plurality of connecting holes is arranged corresponding to one of the at least one linear sidewall segment, and in a direction substantially perpendicular to the pixel driving layer, each of the plurality of connecting holes at least partially overlaps with the corresponding one of the at least one linear sidewall segment;
or,
in a case where the number of the linear sidewall segment is at least two, each of the plurality of connecting holes is arranged corresponding to adjacent two of the at least two linear sidewall segments of the same isolation structure, and in the direction substantially perpendicular to the pixel driving layer, each of the plurality of connecting holes partially overlaps with each of the corresponding adjacent two of the at least two linear sidewall segments.

4. The display panel as claimed in claim 2, wherein the anode is disposed in a corresponding one of the plurality of pixel openings, extends into a corresponding one of the plurality of connecting holes, and further covers a sidewall of the corresponding one of the plurality of connecting holes, enabling the anode to be electrically connected to the pixel driving layer through the corresponding one of the plurality of connecting holes; and
a conductive groove is defined and surrounded by a part of the anode that is located in the corresponding one of the plurality of connecting holes, the conductive groove is arranged in a one-to-one correspondence with the plurality of connecting holes, and an orthographic projection of the conductive groove on the pixel driving layer is located within an orthographic projection of the corresponding one of the plurality of connecting holes on the pixel driving layer.

5. The display panel as claimed in claim 4, wherein in a direction substantially perpendicular to the pixel driving layer, the sidewall of the isolation structure comprises a conductive portion and an eave structure sequentially stacked on one another, and the eave structure shields the conductive portion and extends beyond the conductive portion in a direction substantially parallel to a plane where the pixel defining layer is located; and
an orthographic projection of the conductive portion on the pixel driving layer covers an orthographic projection of the conductive groove on the pixel driving layer.

6. The display panel as claimed in claim 4, wherein a width direction of the conductive groove refers to a wall thickness direction of the sidewall of the isolation structure corresponding to the conductive groove; and
a width of a groove opening of the conductive groove is a first size, and the first size is less than 4 μm.

7. The display panel as claimed in claim 6, wherein a length direction of the conductive groove refers to an extending direction of the sidewall of the isolation structure corresponding to the conductive groove; and
in the length direction, an extending length from an end of the groove opening to another end of the groove opening is a second size, and the second size is greater than the first size.

8. The display panel as claimed in claim 5, wherein a pattern formed by the orthographic projection of the conductive groove on the pixel driving layer is a first projection pattern, a pattern formed by the orthographic projection of the conductive portion on the pixel driving layer is a second projection pattern, and an edge of the first projection pattern and an edge of the corresponding second projection pattern that are adjacent to each other are substantially arranged in parallel.

9. The display panel as claimed in claim 8, wherein the isolation structure has substantially a rectangular ring structure, and each of the plurality of sub-pixels is substantially rectangular in shape; and
the conductive groove is defined at a corner of the rectangular ring structure, and the first projection pattern is substantially L-shaped;
or,
the conductive groove is defined corresponding to an edge of the rectangular ring structure, and the first projection pattern is substantially rectangular in shape.

10. The display panel as claimed in claim 5, wherein a recess is defined on a surface of a part of the pixel definition layer corresponding to the conductive groove and facing away from the pixel driving layer; and
in a case where the conductive portion and the eave structure are disposed in the recess, the recess is further defined on a surface of a side of each of the conductive portion and the eave structure that faces away from the pixel driving layer.

11. A display device, comprising a display panel,
wherein the display panel comprises:
a pixel driving layer;
a planarization layer, covering the pixel driving layer and defining a plurality of connecting holes;
a pixel defining layer, disposed on a side of the planarization layer away from the pixel driving layer and defining a plurality of pixel openings;
a plurality of sub-pixels, each of the plurality of sub-pixels being disposed in a corresponding one of the plurality of pixel openings, wherein an anode of each of the plurality of sub-pixels is electrically connected to the pixel driving layer through a corresponding one of the plurality of connecting holes; and
an isolation structure, protruding from the pixel defining layer and surrounding the plurality of pixel openings;
wherein, in a surrounding direction of the isolation structure, a sidewall of the isolation structure comprises a sidewall segment extending linearly, the number of the sidewall segment extending linearly is at least one, and the sidewall segment extending linearly is defined as a linear sidewall segment; and
an orthographic projection of the sidewall of the isolation structure projected on the planarization layer covers the plurality of connecting holes, and an orthographic projection of the linear sidewall segment on the planarization layer at least partially covers the plurality of connecting holes.

12. The display device as claimed in claim 11, wherein the plurality of connecting holes are arranged in a one-to-one correspondence with the plurality of sub-pixels, and in a direction substantially parallel to the pixel driving layer, the plurality of connecting holes extend along an extending direction of the sidewall.

13. The display device as claimed in claim 11, wherein each of the plurality of connecting holes is arranged corresponding to one of the at least one linear sidewall segment, and in a direction substantially perpendicular to the pixel driving layer, each of the plurality of connecting holes at least partially overlaps with the corresponding one of the at least one linear sidewall segment;
or,
in a case where the number of the linear sidewall segment is at least two, each of the plurality of connecting holes is arranged corresponding to adjacent two of the at least two linear sidewall segments of the same isolation structure, and in the direction substantially perpendicular to the pixel driving layer, each of the plurality of connecting holes partially overlaps with each of the corresponding adjacent two of the at least two linear sidewall segments.

14. The display device as claimed in claim 12, wherein the anode is disposed in a corresponding one of the plurality of pixel openings, extends into a corresponding one of the plurality of connecting holes, and further covers a sidewall of the corresponding one of the plurality of connecting holes, enabling the anode to be electrically connected to the pixel driving layer through the corresponding one of the plurality of connecting holes; and
a conductive groove is defined and surrounded by a part of the anode that is located in the corresponding one of the plurality of connecting holes, the conductive groove is arranged in a one-to-one correspondence with the plurality of connecting holes, and an orthographic projection of the conductive groove on the pixel driving layer is located within an orthographic projection of the corresponding one of the plurality of connecting holes on the pixel driving layer.

15. The display device as claimed in claim 14, wherein in a direction substantially perpendicular to the pixel driving layer, the sidewall of the isolation structure comprises a conductive portion and an eave structure sequentially stacked on one another, and the eave structure shields the conductive portion and extends beyond the conductive portion in a direction substantially parallel to a plane where the pixel defining layer is located; and
an orthographic projection of the conductive portion on the pixel driving layer covers an orthographic projection of the conductive groove on the pixel driving layer.

16. The display device as claimed in claim 14, wherein a width direction of the conductive groove refers to a wall thickness direction of the sidewall of the isolation structure corresponding to the conductive groove; and
a width of a groove opening of the conductive groove is a first size, and the first size is less than 4 μm.

17. The display device as claimed in claim 16, wherein a length direction of the conductive groove refers to an extending direction of the sidewall of the isolation structure corresponding to the conductive groove; and
in the length direction, an extending length from an end of the groove opening to another end of the groove opening is a second size, and the second size is greater than the first size.

18. The display device as claimed in claim 15, wherein a pattern formed by the orthographic projection of the conductive groove on the pixel driving layer is a first projection pattern, a pattern formed by the orthographic projection of the conductive portion on the pixel driving layer is a second projection pattern, and an edge of the first projection pattern and an edge of the corresponding second projection pattern that are adjacent to each other are substantially arranged in parallel.

19. The display device as claimed in claim 18, wherein the isolation structure has substantially a rectangular ring structure, and each of the plurality of sub-pixels is substantially rectangular in shape; and
the conductive groove is defined at a corner of the rectangular ring structure, and the first projection pattern is substantially L-shaped;
or,
the conductive groove is defined corresponding to an edge of the rectangular ring structure, and the first projection pattern is substantially rectangular in shape.

20. The display device as claimed in claim 15, wherein a recess is defined on a surface of a part of the pixel definition layer corresponding to the conductive groove and facing away from the pixel driving layer; and
in a case where the conductive portion and the eave structure are disposed in the recess, the recess is further defined on a surface of a side of each of the conductive portion and the eave structure that faces away from the pixel driving layer.
